(19) United States
(12) Patent Application Publication
(10) Pub. No.: US 2023/0187189 A1
(43) Pub. Date: Jun. 15, 2023

(54) PLASMA CONTROL APPARATUS AND PLASMA PROCESSING SYSTEM

(71) Applicant: Samsung Electronics Co., Ltd., Suwon-si (KR)

(72) Inventors: Myungsub Jung, Seoul (KR); Sungyeol Kim, Yongin-si (KR); Sungyong Lim, Seoul (KR); Jaehyun Choi, Suwon-si (KR); Kyungmin Lee, Gwacheon-si (KR); Seungkyu Lim, Uiwang-si (KR)

(21) Appl. No.: 17/864,541

(22) Filed: Jul. 14, 2022

(30) Foreign Application Priority Data
Dec. 14, 2021 (KR) 10-2021-0178621

(51) Int. Cl. H01J 37/32; C23C 16/52; C23C 16/509

(52) U.S. Cl. CPC H01J 37/32935; H01J 37/32541; H01J 37/32568; H01J 37/32926; C23C 16/52; C23C 16/509; H01J 2237/24564; H01J 2237/3321; H01J 37/32183

(57) ABSTRACT

a plasma processing system includes a chamber providing a space for performing a plasma process on a substrate, a substrate stage having a seating surface for supporting the substrate, the substrate stage having a circular electrode and at least one annular electrode therein, an upper electrode provided over the substrate, a power supply configured to supply source power to the upper electrode, a first capacitance variator configured to vary a capacitance of the circular electrode based on an inputted first control signal, a second capacitance variator configured to vary a capacitance of the annular electrode based on an inputted second control signal, a sensor connected to the first and second capacitance variators respectively and configured to acquire electrical signal data of the circular electrode and the at least one annular electrode, and a controller configured to determine a thin film profile in first and second regions of the substrate corresponding to the circular electrode and the annular electrode respectively based on the electrical signal data obtained from the sensor, the controller being configured to output the first and second control signals respectively in order to obtain a desired thin film profile.

### PRIORITY STATEMENT

This application claims priority under 35 U.S.C. § 119 to Korean Patent Application No. 10-2021-0178621, filed on Dec. 14, 2021 in the Korean Intellectual Property Office (KIPO), the contents of which are herein incorporated by reference in their entirety.

### BACKGROUND

### 1. Field

Example embodiments relate to a plasma control apparatus and a plasma processing system. More particularly, example embodiments relate to a plasma control apparatus configured to control plasma in semiconductor processing equipment using plasma and a plasma processing system including the same.

### 2. Description of the Related Art

In a semiconductor manufacturing process using plasma (CVD, Etcher, etc.), it is necessary to control plasma characteristics in order to control process distribution. Recently, gas, temperature, plasma distribution, etc. are controlled in various process processes, but more detailed control may be helpful for process distribution. In particular, in a semiconductor thin film process, it is difficult to control each film process stage of multiple films for securing the uniformity of the thin film, and the thin film may be non-uniform according to the change of the facility environment.

### SUMMARY

Example embodiments provide a plasma processing system including a substrate stage having a circular electrode and an annular electrode for actively controlling a thin film on each region of a semiconductor substrate.

Example embodiments provide a plasma processing method using the plasma processing system.

According to example embodiments, a plasma processing system includes a chamber providing a space for performing a plasma process on a substrate, a substrate stage having a seating surface for supporting the substrate, the substrate stage having a circular electrode and at least one annular electrode therein, an upper electrode provided over the substrate, a power supply configured to supply source power to the upper electrode, a first capacitance variator configured to vary a capacitance of the circular electrode based on an inputted first control signal, a second capacitance variator configured to vary a capacitance of the annular electrode based on an inputted second control signal, a sensor connected to the first and second capacitance variators respectively and configured to acquire electrical signal data of the circular electrode and the at least one annular electrode, and a controller configured to determine a thin film profile in first and second regions of the substrate corresponding to the circular electrode and the annular electrode respectively based on the electrical signal data obtained from the sensor, the controller being configured to output the first and second control signals respectively in order to obtain a desired thin film profile.

According to example embodiments, a plasma processing system includes a substrate stage having a seating surface for supporting a substrate having first and second regions, the substrate stage having a first electrode and at least one second electrode therein, the first electrode corresponding to the first region, and the at least one second electrode corresponding to the second region, an upper electrode provided over the substrate, a power supply configured to supply source power to the upper electrode, a capacitance variator configured to independently vary capacitance of the first electrode and of the at least one second electrode, a sensor configured to acquire electrical signal data of the first electrode and the at least one second electrode to check deposition rates in the first and second regions, and a controller configured to determine a thin film profile in each of the first and second regions of the substrate based on the electrical signal data obtained from the sensor, the controller being configured to vary the capacitance of the first electrode and the at least one second electrode through the capacitance variator in order to obtain a desired thin film profile.

According to example embodiments, a plasma processing system includes a chamber providing a space for performing a plasma process on a substrate, a substrate stage having a seating surface for supporting the substrate, the substrate stage having a circular electrode and at least one annular electrode therein, a power supply configured to supply source power to an upper electrode provided on the substrate, a first impedance variator configured to vary an impedance of the circular electrode, a second impedance variator configured to vary an impedance of the at least one annular electrode, a sensor connected to the first and second impedance variators respectively and configured to acquire electrical signal data of the circular electrode and the at least one annular electrode, and a controller configured to determine a thin film profile based on the electrical signal data obtained from the sensor in first and second regions of the substrate respectively corresponding to the circular electrode and the annular electrode, the controller being configured to output first and second control signals respectively in order to obtain a desired thin film profile by using big data having a correlation between the electrical signal data and a deposition rate of the substrate.

According to example embodiments, a plasma processing system may include a chamber providing a space for performing a plasma process on a substrate, a substrate stage having a seating surface for supporting the substrate, the substrate stage having a circular electrode and at least one annular electrode therein, an upper electrode provided over the substrate, a power supply configured to supply source power to the upper electrode, a first capacitance variator configured to vary a capacitance of the circular electrode based on an inputted first control signal, a second capacitance variator configured to vary a capacitance of the annular electrode based on an inputted second control signal, a sensor connected to the first and second capacitance variators respectively to acquire electrical signal data of the circular electrode and the at least one annular electrode, and a controller configured to determine a thin film profile in first and second regions of the substrate corresponding to the circular electrode and the annular electrode respectively based on the electrical signal data obtained from the sensor, the controller being configured to output the first and second control signals respectively for obtaining a desired thin film profile.

Thus, by using the circular electrode and the annular electrode, the substrate may be divided into regions for active control, and the controller may control the first and second capacitance variators in real time by using the electrical signal data collected by the sensor. Accordingly, since the controller may more precisely control characteristics of the plasma existing inside the chamber and actively respond to environmental changes, it is possible to perform a uniform deposition process on the substrate.

### BRIEF DESCRIPTION OF THE DRAWINGS

Example embodiments will be more clearly understood from the following detailed description taken in conjunction with the accompanying drawings. FIGS. 1 to 7 represent non-limiting, example embodiments as described herein.

FIG. 1 is a block diagram illustrating a plasma processing system for a semiconductor device in accordance with example embodiments.

FIG. 2 is a cross-sectional view illustrating a substrate stage in FIG. 1 in accordance with example embodiments.

FIG. 3 is a cross-sectional view taken along the line A-A′ in FIG. 2 in accordance with example embodiments.

FIG. 4 is a plan view illustrating regions of semiconductor device to be processed.

FIG. 5 is an enlarged cross-sectional view illustrating portion ‘B’ in FIG. 2.

FIG. 6 is an enlarged cross-sectional view illustrating portion ‘C’ in FIG. 5.

FIG. 7 is a flow chart illustrating a plasma control method in accordance with example embodiments.

### DETAILED DESCRIPTION OF EXAMPLE EMBODIMENTS

Hereinafter, example embodiments will be explained in detail with reference to the accompanying drawings.

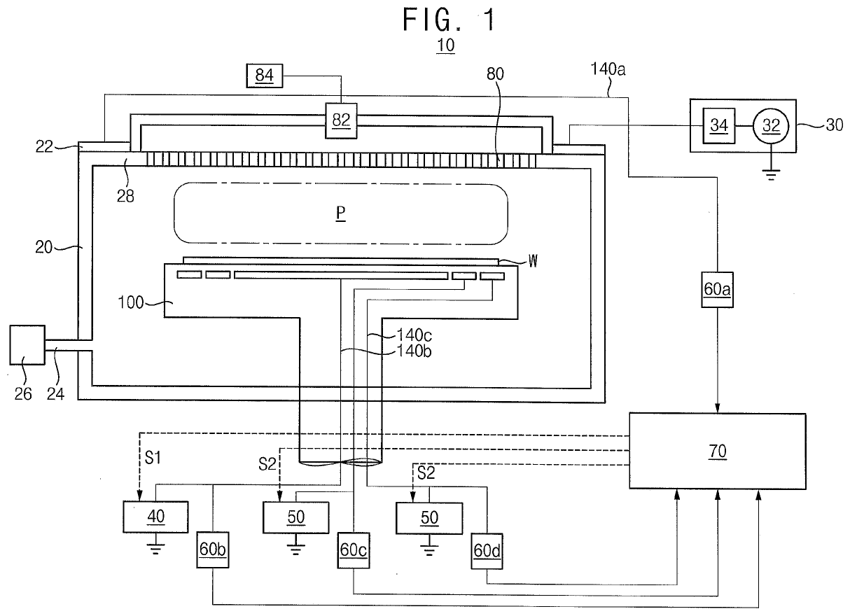

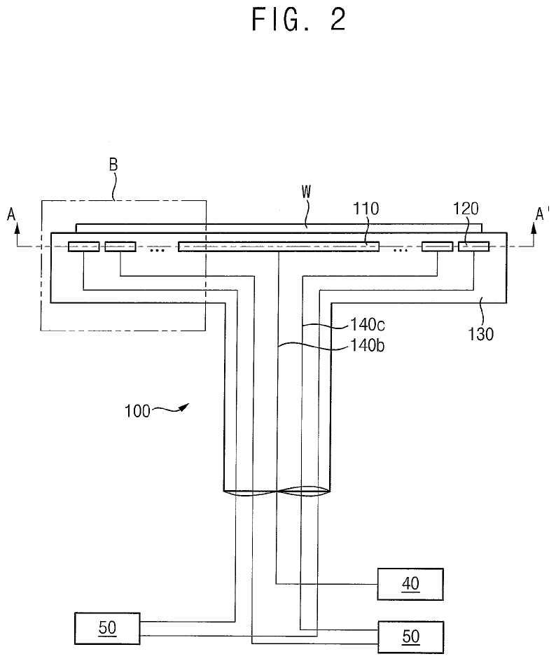

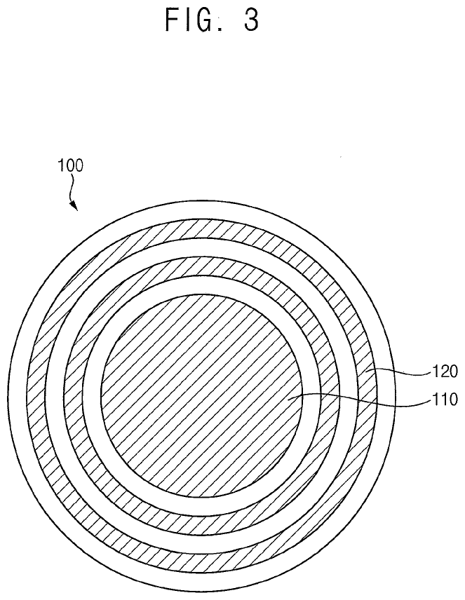

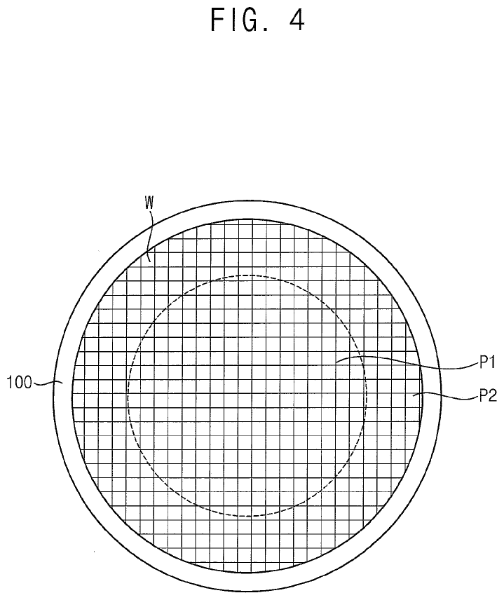

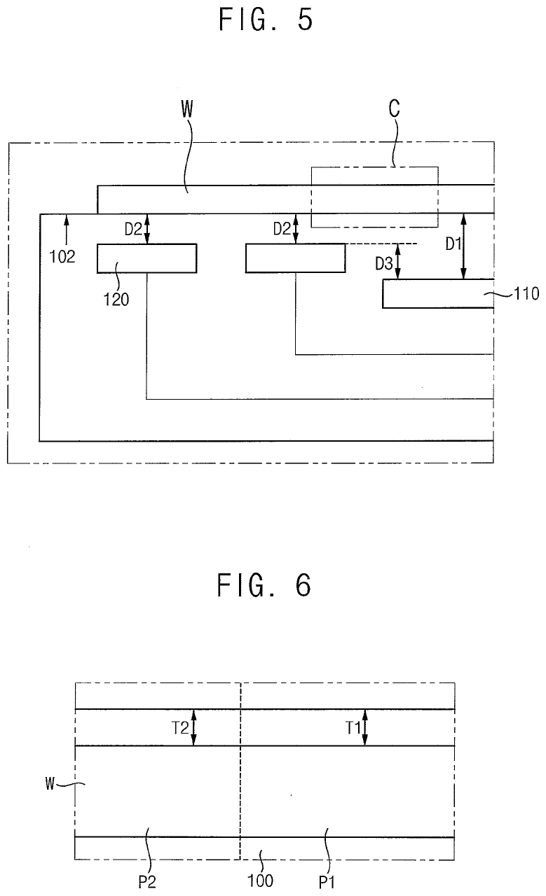

FIG. 1 is a block diagram illustrating a plasma processing system for a semiconductor device in accordance with example embodiments. FIG. 2 is a cross-sectional view illustrating a substrate stage in FIG. 1 in accordance with example embodiments. FIG. 3 is a cross-sectional view taken along the line A-A′ in FIG. 2 in accordance with example embodiments. FIG. 4 is a plan view illustrating regions of semiconductor device to be processed. FIG. 5 is an enlarged cross-sectional view illustrating portion ‘B’ in FIG. 2. FIG. 6 is an enlarged cross-sectional view illustrating portion ‘C’ in FIG. 5.

Referring to FIGS. 1 to 6, a plasma processing system 10 may include a chamber 20 providing a space for performing a plasma process on a substrate, a substrate stage 100 having a seating surface for supporting the substrate, and a plasma control apparatus configured to form and control plasma on the substrate in the chamber 20. The plasma control apparatus may include an upper electrode 22, a power supply 30, a capacitance variator, a sensor 60 (e.g., 60a-60d) and a controller 70. The capacitance variator may include a first capacitance variator 40 and a second capacitance variator 50.

The plasma processing system 10 may be a system configured to deposit a target film on the substrate such as a semiconductor wafer disposed in the chamber 20 for a plasma enhanced chemical vapor deposition (PECVD) process. However, the plasma processing system 10 is not necessarily limited to a deposition apparatus. For example, the plasma processing system may be used as an etching apparatus, a cleaning apparatus, and the like. Here, the substrate may include a semiconductor substrate, a glass substrate, or the like.

The plasma processing system 10 may be a capacitively coupled plasma (CCP) processing apparatus. However, the plasma generated by the plasma processing apparatus is not limited to the capacitively coupled plasma, and may include inductively coupled plasma or microwave type plasma.

The plasma enhanced chemical vapor deposition process may be referred to as a chemical process in which electromagnetic energy is applied to at least one precursor gas or precursor vapor to convert the precursor into a reactive plasma. The plasma enhanced chemical vapor deposition process may be used to deposit materials such as blanket dielectric films on semiconductor devices such as the semiconductor wafer W. For example, the plasma P may be generated in-situ inside the chamber 20. Alternatively, the plasma P may be generated in a remote plasma generator that is installed to be spaced apart from the chamber 20.

In example embodiments, the chamber 20 may provide an enclosed space for performing a plasma deposition process on the wafer W. The chamber 20 may be a cylindrical vacuum chamber. The chamber 20 may include or be formed of a metal such as aluminum or stainless steel. For example, the chamber 20 may be referred to as a plasma processing chamber having a tuning electrode inside the substrate stage 100 for enhanced processing rate and plasma profile uniformity.

The substrate stage 100 for supporting the substrate may be disposed inside the chamber 20. For example, the substrate stage 100 may serve as a susceptor for supporting the wafer W. The substrate stage 100 may include an electrostatic chuck for holding the wafer W by electrostatic attraction thereon. The electrostatic chuck may adsorb and hold the wafer W with an electrostatic power by a DC voltage supplied from a DC power supply.

A wafer W may be mounted on an upper surface of the electrostatic chuck, and a focus ring (not shown) may be mounted around the wafer W. As will be described later, a substrate electrode may be disposed under the wafer W. In addition, the substrate electrode may have a circulation channel (not shown) for cooling therein. Also, a cooling gas such as He gas may be supplied between the electrostatic chuck and the wafer W for precision of wafer temperature.

A gate (not shown) for loading and unloading the wafer W may be installed in a sidewall of the chamber 20. The wafer W may be loaded and unloaded onto the substrate stage 100 through the gate.

An exhaust port 24 may be installed in a lower portion of the chamber 20, and an exhaust device 26 may be connected to the exhaust port 24 through an exhaust pipe. The exhaust device 26 may be or may include a vacuum pump such as a turbo molecular pump to depressurize the processing space inside the chamber 20 to a desired degree of vacuum. Also, process byproducts and residual process gases generated in the chamber 20 may be discharged through the exhaust port 24.

The chamber 20 may include a cover 28 covering an upper portion of the chamber 20. The cover 28 may seal the upper portion of the chamber 20.

The upper electrode 22 may be disposed on an outer side of the chamber 20 to face the substrate electrode. The upper electrode 22 may be disposed on the cover 28. A chamber space between the upper electrode 22 and the substrate electrode may be used as a plasma generating region. The upper electrode 22 may have a surface facing the wafer W on the substrate stage 100. For example, a lower surface of upper electrode 22 may face a downward direction extending toward the wafer W and substrate stage 100.

The upper electrode 22 may be supported by an insulating shielding member (not shown) above the chamber 20. The upper electrode 22 may include an electrode plate having a circular shape. The upper electrode 22 may have a plurality of supply holes (not shown) that are formed to penetrate through the upper electrode 22 to supply a gas into the chamber 20.

The power supply 30 may supply plasma source power to the upper electrode 22. The power supply 30 may be connected to the upper electrode 22 through a first signal line 140a. For example, the power supply 30 may include a high frequency generator 32 and a matcher 34 as plasma source elements. The high frequency generator 32 may generate a high frequency (RF) signal. The matcher 34 may match an output impedance of the RF signal generated by the high frequency generator 32 to control the plasma P to be generated using the upper electrode 22. The matcher 34 may control the output impedance by changing an internal capacitor (e.g., changing the capacitance of an internal capacitor).

In example embodiments, the substrate stage 100 may include a substrate support 130 having the seating surface 102 for supporting the substrate, and a substrate electrode provided in the substrate support 130. The substrate electrode may include a first electrode 110 and at least one second electrode 120. For example, the substrate stage 100 may include a conductor such as a radio frequency (RF) electrode, a clamping electrode, a resistance heating element, etc. therein or thereon, and may serve as a heater or the electrostatic chuck.

The substrate support 130 may include or be formed of one or more metallic or ceramic materials. For example, the metallic or ceramic materials may include at least one metal, metal oxides, metal nitrides, metal oxynitrides, or a combination thereof. The substrate support 130 may include or be formed of aluminum, aluminum oxide, aluminum nitride, aluminum oxynitride, or a combination thereof.

The first electrode 110 may be or may include a circular electrode having a disk shape, and the second electrode 120 may be or may include an annular electrode having a circular ring shape surrounding the circular electrode. For the purposes of this specification, the term “circular electrode” refers to an electrode having a full circular shape and does not include an electrode having a ring shape with a concentric hole or space inside when viewed from a plan view. The circular electrode 110 may have a first impedance value, and the annular electrode 120 may have a second impedance value independent of the first impedance value. The circular electrode 110 and the annular electrode 120 may include or be formed of at least one electrically conductive metal. For example, the circular electrode 110 and the annular electrode 120 may include or be formed of aluminum, copper, or any alloys thereof. The circular electrode 110 and the annular electrode 120 may be formed of the same material as each other, or different materials from each other.

The circular electrode 110 may have a surface area greater than a surface area of the annular electrode 120. The annular electrode 120 may have a diameter greater than a diameter of the circular electrode 110. The annular electrode 120 may surround the circular electrode 110. For example, the annular electrode 120 may laterally overlap the circular electrode 110 at least partially. The annular electrode 120 may be positioned laterally near the circular electrode 110 and may be positioned on a same plane or on different planes. For example, the annular electrode 120 may be positioned at the same vertical level as the circular electrode 110 (e.g., to have top and bottom surfaces on the same horizontal planes as respective top and bottom surfaces of the circular electrode 110, or to have at least a portion on the same horizontal plane as at least a portion of the circular electrode 110), or the annular electrode 120 may be positioned at a different vertical level as the circular electrode (e.g., to share no common horizontal planes).

The circular electrode 110 may have a disk shape. However, other shapes of electrode can be used instead of disk-shaped circular electrode 110. As illustrated in FIGS. 3 and 4, the circular electrode 110 may be provided at a position corresponding to a first region P1 of the wafer W inside the substrate support 130. The first region P1 may be referred to as a central region of the wafer W.

The circular electrode 110 may be embedded in the substrate support 130. Alternatively, the circular electrode 110 may be provided to be exposed on a surface of the substrate support 130. The circular electrode 110 may include a plate, a perforated plate, a wire screen, or any other distributed arrangement. The circular electrode 110 may include or may be a sheet type or a mesh type.

The annular electrode 120 may surround an outer side of the circular electrode 110 and may be spaced apart from the circular electrode 110. The annular electrode 120 may have a circular ring shape. However, the shape of the annular electrode 120 is not limited to the circular ring shape. For example, the number of the annular electrodes 120 may be within a range of 1 to 3. A plurality of ring-shaped electrodes may be referred to as a single annular electrode, or each individual ring-shaped electrode may be referred to as an annular electrode. As illustrated in FIGS. 3 and 4, the annular electrode 120 may be provided at a position corresponding to a second region P2 of the wafer W inside the substrate support 130. The second region P2 may be referred to as a peripheral portion of the wafer W.

The annular electrode 120 may be embedded in the substrate support 130. Alternatively, the annular electrode 120 may be provided to be exposed on the surface of the substrate support 130. The annular electrode 120 may include a plate, a perforated plate, a wire screen, or any other distributed arrangement. The annular electrode 120 may include or may be a sheet type or the mesh type.

As illustrated in FIG. 5, the circular electrode 110 may have a first distance D1 from the seating surface 102 of the substrate stage 100, in a vertical direction perpendicular to the surface of the substrate stage 100, and the annular electrode 120 may have a second distance D2 from the seating surface 102 in the vertical direction perpendicular to the surface of the substrate stage 100. The seating surface 102 may be referred to as an upper surface of the substrate stage 100. A difference D3 between the first and second distances may be within a range of 0.1 mm to 2.0 mm. For example, the distance D1 may refer to a vertical distance between an upper surface of the substrate stage 100 and an upper surface of the circular electrode 110, and the distance D2 may refer to a vertical distance between the upper surface of the substrate stage 100 and an upper surfaced of the annular electrode 120. In one embodiment, the upper surface of the circular electrode 110 is at a different vertical level as, and is not coplanar with, the upper surface of the annular electrode 120.

In example embodiments, the circular electrode 110, the upper electrode 22, the power supply 30, and the first capacitance variator 40 may constitute one electrically connected first circuit path. The annular electrode 120, the upper electrode 22, the power supply 30, and the second capacitance variator 50 may constitute one electrically connected second circuit path.

The capacitor variator may vary capacitance of the first electrode (the circular electrode 110) and the second electrode (the annular electrode 120) independently of each other. For example, the circular electrode 110 and the first capacitance variator 40 may be provided in parallel with the annular electrode 120 and the second capacitance variator 50 in one circuit with the upper electrode 22 and the power supply 30. The capacitance variator may serve as an impedance variable unit to vary the impedance values of the first and second electrodes by varying their capacitance. For example, the capacitance variator 40 may include one or more known variable capacitors formed in parallel with annular electrode 120, and the capacitance variator 50 may include one or more known variable capacitors formed in parallel with the circular electrode 110. For example, digitally tuned capacitors such as an integrated circuit variable capacitor may be used.

Specifically, the first capacitance variator 40 may vary the capacitance of the circular electrode 110 based on an inputted first control signal S1. For example, the first capacitance variator 40 may be connected to the circular electrode 110 by a second signal line 140b. The capacitance of the first capacitance variator 40 may be varied by the first control signal S1 from the controller 70 to control a deposition rate of the first region P1 of the wafer W.

The second capacitor variator 50 may vary the capacitance of the annular electrode 120 based on an inputted second control signal S2. For example, the second capacitor variator 50 may be connected to the annular electrode 120 by a third signal line 140c. The capacitance of the second capacitance variator 50 may be varied by the second control signal S2 from the controller 70 to control a deposition rate of the second region P2 of the wafer W. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

In addition, the first capacitor variator 40 may vary the capacitance of the circular electrode 110 to control the deposition rate of the second region P2, and the first capacitor variator 40 may vary the capacitance of the annular electrode 120 to control the deposition rate of the first region P1. The first and second capacitor variators 40 and 50 may simultaneously vary the capacitances of the circular electrode 110 and the annular electrode 120 respectively, to simultaneously vary the deposition rates of the first region P1 and the second region P2. For example, the capacitance of the circular electrode 110 with respect to the upper electrode 22 may affect the deposition rate within the first region P1 and second region P2. Similarly, the capacitance of the annular electrode 120 with respect to the upper electrode 22 may affect the deposition rate within the first region P1 and the second region P2. Therefore, varying these capacitances can be used to control and adjust the deposition rate within the first region P1 and second region P2.

In example embodiments, the plasma processing system 10 may further include a gas supply for supplying a gas into the chamber 20. For example, the gas supply may include gas supply lines 80, a flow controller 82 and a gas source 84, such as gas supply elements. The gas supply lines 80 may be connected to the upper portion and/or side portion of the chamber 20 to supply various gases into the chamber 20 therethrough. For example, the gas supply lines 80 may include a vertical gas supply line which penetrates through the cover 28 and a horizontal gas supply line which penetrates through the sidewall of the chamber 20. The vertical gas supply line and the horizontal gas supply line may directly supply various gases to the plasma space in the chamber 20.

The gas supply may supply different gases having a desired mixture ratio. The gas source 84 may store a plurality of gases and the gases may be supplied through a plurality of gas lines respectively connected to the gas supply lines 80. The flow controller 82 may control supply flow rates of the gases introduced into the chamber 20 through the gas supply lines 80. The flow controller 82 may independently or commonly control the supply flow rates of the gases respectively supplied to the vertical gas supply line and the horizontal gas supply line. For example, the gas source 84 may include a plurality of gas tanks, and the flow controller 82 may include a plurality of mass flow controllers (MFC) respectively corresponding to the gas tanks. The mass flow controllers may each independently control the supply flow rates of the gases.

In example embodiments, the sensor 60 including a plurality of sensors 60a, 60b, 60c and 60d may obtain electrical signal data of matcher 34, the circular electrode 110 and the annular electrode 120 to check the deposition rates of the first region P1 and the second region P2 of the substrate.

For example, the sensor may include a voltage current sensor (VI sensor). The voltage current sensor may detect voltage, current, and phase difference of harmonics in addition to a main frequency. The voltage current sensor may analyze harmonics of the RF signal.

The voltage current sensor may be installed in the signal line 140 to detect changes in electrical characteristics of the matcher 34, the circular electrode 110 and the annular electrode 120. For example, the changes in electrical characteristics may be determined based on electrical signal data of the RF signal received at the matcher 34, the circular electrode 110 and the annular electrode 120, which data may include values for power, current, voltage, phase, and micro arcing.

The voltage current sensor may determine each of the matcher 34, the circular electrode 110 and the annular electrode 120 as a kind of equivalent circuit. The voltage current sensor may measure the electrical signal data and measure harmonics, for example, through fast Fourier transform. The electrical signal data may depend very sensitively on a state of the plasma and reactor. Accordingly, the measurements made by the voltage current sensor may be used to determine plasma density, electron temperature, and a change in a composition of a material present in the plasma or a small change in a reactor surface state.

In example embodiments, the controller 70 may determine a thin film profile in the first and second regions P1, P2 of the substrate corresponding to the circular electrode 110 and the annular electrode 120, respectively, based on the electrical signal data obtained from the sensor 60. For example, the controller 70 can determine how the thin film is being deposited—e.g., the evenness, the thickness, etc., at different locations. The controller 70 may output the first and second control signals S1, S2 respectively, which are used to vary capacitance of the circular electrode 110 and the annular electrode 120 to control and adjust deposition rates, to obtain a desired thin film profile. For example, a thin film on the first region P1 where the circular electrode 110 is located may have a first thin film thickness, and a thin film on the second region P2 where the annular electrode 120 is located may have a second thin film thickness, and the controller 70 may be configured to output the first and second control signals S1 and S2 such that a difference between the first thin film thickness and the second thin film thickness is within a preset range—e.g., the same thickness or a thickness difference within a predetermined variation.

The controller 70 may be connected to the power supply 30 and the first and second capacitance variators 40, 50 to control their operations. The controller 70 may include a microcomputer and various interfaces, and may control the operation of the plasma control apparatus according to program and recipe information stored in an external memory or an internal memory.

Specifically, the controller 70 may generate a plasma power control signal and a bias power control signal, respectively. The power supply 30 may apply the plasma source power to the upper electrode 22 according to the plasma power control signal.

The power supply 30 may apply a high frequency power signal to the upper electrode 22 according to the plasma power control signal. For example, a high frequency power may be generated as RF power having a frequency range of about 27 MHz to 2.45 GHz and a power range of about 100 W to 1000 W. For example, the high frequency power may be mainly generated to have a frequency of about 40 MHz to about 1.5 GHz.

When the high frequency power having a predetermined frequency is applied to the upper electrode 22, an electromagnetic field induced by the upper electrode 22 may be applied to source gas injected into the chamber 20 to generate plasma P.

The controller 70 may receive the electrical signal data from the sensor 60. For example, the electrical signal data may include values corresponding to power, current, voltage, phase, and micro arcing.

The controller 70 may determine whether a deposition process having a desired distribution is performed on the wafer W by analyzing the electrical signal data. The controller 70 may include big data having a correlation between the electrical signal data and the deposition rate, and may determine whether the deposition process having a desired distribution is being performed on the substrate by using the big data.

The big data may include data on a causal relationship between the circular electrode 110, the annular electrode 120, the wafer W, the plasma P and the upper electrode 22, which occurs during the deposition process. Accordingly, the controller 70 may determine and control an overall progress of the deposition process using the electrical signal data collected by the sensor 60. The term “big data” refers to data sets that are too large or complex to be dealt with by traditional data-processing application software.

The controller 70 may use a deep learning technology when comparing the collected electrical signal data with the big data. Since the amount of data collected by the sensor 60 and the amount of data stored in the controller 70 may be too large or complex to process with traditional methods, it may be difficult to compare them using such methods. In addition, when the mutual influence of each sensor is considered, the amount of data may be further increased. Therefore, in case of using the deep learning technology, it may be possible to summarize key contents in a large amount of data, thereby performing effective data comparison. Deep learning refers to a type of machine learning based on artificial neural networks in which multiple layers of processing are used to extract progressively higher level features from data.

The controller 70 may transmit the first control signal S1 to the first capacitance variator 40 in order to obtain the desired thin film profile in the first region P1 of the substrate. The controller 70 may transmit the second control signal S2 to the second capacitance variator 50 in order to obtain the desired thin film profile in the second region P2 of the substrate. The controller 70 may transmit the first and second control signals S1 and S2 to the first and second capacitance variators 40 and 50 when a problem occurs in the desired deposition process. For example, if it is determined that deposition is not uniform, control signals S1 and S2 can be used to change capacitances of the circular electrode 110 and annular electrode 120, which will alter the deposition rate at different regions of a substrate. This determination and control can be performed automatically as a result of, for example, using deep learning technology with big data. For example, the thin film profile may be determined through the iteratively performed deposition process. The thin film profile may be determined through a set of the electrical signal data acquired through the plurality of deposition processes. In the iterative deposition process, the desired thin film profile can be determined.

As illustrated in FIG. 6, the controller 70 may control the first and second capacitance variators 40, 50 to obtain a uniform thin film thickness on the wafer W. Specifically, the thin film on the first region P1 of the substrate may have a first thin film thickness T1, and the thin film on the second region P2 of the substrate may have a second thin film thickness T2. The controller 70 may control the first and second capacitance variators 40, 50 such that the first and second thin film thicknesses T1 and T2 are the same.

As described above, the circular electrode 110 and the annular electrode 120 may actively control the deposition of the substrate by dividing the substrate by regions, and the controller 70 may control the first and second capacitance variators 40, 50 in real time by using the electrical signal data obtained by the sensor 60. Accordingly, the controller 70 may more precisely control the characteristics of the plasma existing inside the chamber 20 and may actively respond to environmental changes, so that it may be possible to perform a uniform deposition process on the substrate.

Hereinafter, a method of using the plasma processing system for the semiconductor device in FIG. 1 will be explained.

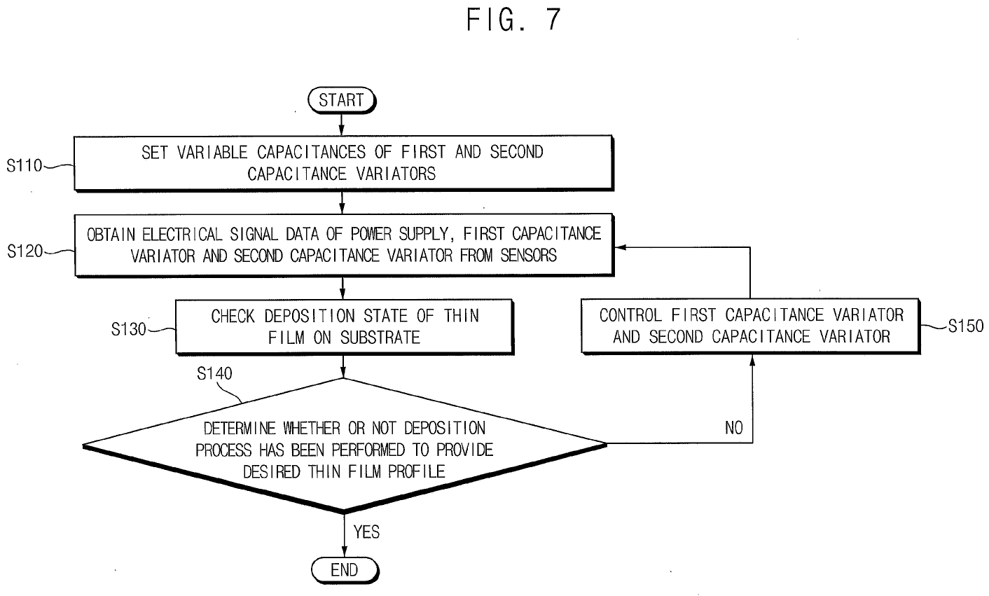

FIG. 7 is a flow chart illustrating a plasma control method in accordance with example embodiments.

Referring to FIGS. 1 to 7, a plasma processing system 10 may form a uniformly deposited film on a substrate by using a chamber 20, a power supply 30, first and second capacitance variators 40, 50, a sensor 60, a controller 70 and a substrate stage 100. The substrate may include a semiconductor substrate, a glass substrate, a semiconductor wafer W, and the like.

First, variable capacitances of the first and second capacitance variators 40, 50 may be set (S110).

In example embodiments, the controller 70 may set the variable capacitance of the first capacitance variator 40 and the variable capacitance of the second capacitance variator 50 in order to form a uniform deposition film on the substrate. The first capacitance variator 40 may be connected to the circular electrode 110 of the substrate stage 100, and the second capacitance variator 50 may be connected to the annular electrode 120 of the substrate stage 100. The plasma processing system 10 may perform a deposition process according to the set variable capacitances.

Then, electrical signal data of the power supply 30, the first capacitance variator 40 and the second capacitance variator 50 may be obtained from a plurality of the sensors 60 (S120), and a deposition state of the thin film on the substrate may be checked (S130).

In example embodiments, the sensor 60 may obtain the electrical signal data from each of the power supply 30, the first capacitance variator 40 and the second capacitance variator 50 to check deposition rates of the first region P1 and the second region P2 of the substrate, respectively.

To determine these deposition rates, the sensor 60 installed in a signal line 140 may detect changes in electrical characteristics of a matcher 34 of the power supply 30, the first capacitance variator 40, and the second capacitance variator 50. For example, the electrical signal data may include values for power, current, voltage, phase, and micro arcing.

Then, whether or not the deposition process has been performed to provide a desired thin film profile may be determined (S140).

In example embodiments, the controller 70 may include big data having a correlation between the electrical signal data and the deposition rate, and may determine whether the deposition process having a desired distribution is in progress on the substrate by using the big data.

Then, the first capacitance variator 40 and the second capacitance variator 50 may be controlled (S150).

In example embodiments, the controller 70 may control the first and second capacitance variators 40, 50 to proceed with the deposition process with the desired thin film profile. The controller 70 may output a first control signal S1 to the first capacitance variator 40 to control the deposition rate of the first region P1 of the substrate. The controller 70 may output a second control signal S2 to the second capacitance variator 50 to control the deposition rate of the second region P2 of the substrate.

Specifically, the thin film on the first region P1 of the substrate may have a first thin film thickness T1, and the thin film on the second region P2 of the substrate may have a second thin film thickness T2. The controller 70 may control the first and second capacitance variators 40, 50 such that the first and second thin film thicknesses T1, T2 are the same. Subsequently, the deposition of the thin film may be completed, additional processes may be performed on the substrate, and a device may be formed. For example, a semiconductor chip may be formed by additional deposition and etching steps, followed by a separation step of dicing a substrate to form a plurality of individual semiconductor chips.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A plasma processing system, comprising:
a chamber providing a space for performing a plasma process on a substrate;
a substrate stage having a seating surface for supporting the substrate, the substrate stage having a circular electrode and at least one annular electrode therein;
an upper electrode provided over the substrate;
a power supply configured to supply source power to the upper electrode;
a first capacitance variator configured to vary a capacitance of the circular electrode based on an inputted first control signal;
a second capacitance variator configured to vary a capacitance of the annular electrode based on an inputted second control signal;
a sensor connected to the first and second capacitance variators respectively and configured to acquire electrical signal data of the circular electrode and the at least one annular electrode; and
a controller configured to determine a thin film profile in first and second regions of the substrate corresponding to the circular electrode and the annular electrode respectively based on the electrical signal data obtained from the sensor, the controller being configured to output the first and second control signals respectively in order to obtain a desired thin film profile.

2. The plasma processing system of claim 1, wherein the number of the annular electrodes is within a range of 1 to 3.

3. The plasma processing system of claim 1, wherein the electrical signal data includes values for power, current, voltage, phase, and micro arcing.

4. The plasma processing system of claim 1, wherein the sensor includes a voltage current sensor (VI sensor).

5. The plasma processing system of claim 1, wherein the circular electrode and the annular electrode include a sheet type or a mesh type.

6. The plasma processing system of claim 1, wherein:
the circular electrode is vertically spaced apart from the seating surface by a first distance,
the annular electrode is vertically spaced apart from the seating surface by a second distance different from the first distance, and
a difference between the first distance and the second distance is within a range of 0.1 mm to 2.0 mm.

7. The plasma processing system of claim 1, wherein the sensor is connected to the power supply to acquire the electrical signal data.

8. The plasma processing system of claim 1, wherein the controller is configured to use big data having a correlation between the electrical signal data and the thin film profile, and to output the first and second control signals using the big data, respectively.

9. The plasma processing system of claim 8, wherein the controller is configured to compare the electric signal data acquired using a deep learning technology with the big data.

10. The plasma processing system of claim 1, wherein:
a thin film on the first region has a first thin film thickness,
a thin film on the second region has a second thin film thickness, and
the controller is configured to output the first and second control signals such that a difference between the first thin film thickness and the second thin film thickness is within a preset range.

11. A plasma processing system, comprising:
a substrate stage having a seating surface for supporting a substrate having first and second regions, the substrate stage having a first electrode and at least one second electrode therein, the first electrode corresponding to the first region, and the at least one second electrode corresponding to the second region;
an upper electrode provided over the substrate;
a power supply configured to supply source power to the upper electrode;
a capacitance variator configured to independently vary capacitance of the first electrode and of the at least one second electrode;
a sensor configured to acquire electrical signal data of the first electrode and the at least one second electrode to check deposition rates in the first and second regions; and
a controller configured to determine a thin film profile in each of the first and second regions of the substrate based on the electrical signal data obtained from the sensor, the controller being configured to vary the capacitances of the first electrode and the at least one second electrode through the capacitance variator in order to obtain a desired thin film profile.

12. The plasma processing system of claim 11, wherein the first electrode has a circular shape and the second electrode has an annular shape surrounding the first electrode.

13. The plasma processing system of claim 11, wherein the electrical signal data includes values for power, current, voltage, phase, and micro arcing.

14. The plasma processing system of claim 11, wherein the sensor includes a voltage current sensor (VI sensor).

15. The plasma processing system of claim 11, wherein:
the capacitance variator includes:
a first capacitor variator configured to vary a capacitance of the first electrode based on an inputted first control signal, and
a second capacitor variator configured to vary a capacitance of the second electrode based on an inputted second control signal; and
the controller is configured to respectively output the first and second control signals based on the determined thin film profiles.

16. The plasma processing system of claim 11, wherein:
the first electrode is spaced apart from the seating surface by a first distance,
the second electrode is spaced apart from the seating surface by a second distance, and
a difference between the first distance and the second distance is within a range of 0.1 mm to 2.0 mm.

17. The plasma processing system of claim 11, wherein the controller is configured to use big data having a correlation between the electrical signal data and the thin film profile, and to output the first and second control signals using the big data, respectively.

18. The plasma processing system of claim 17, wherein the controller is configured to compare the electric signal data acquired using a deep learning technology with the big data.

19. The plasma processing system of claim 11, wherein:
a thin film on the first region has a first thin film thickness,
a thin film on the second region has a second thin film thickness,
the controller is configured to output the first and second control signals such that a difference between the first thin film thickness and the second thin film thickness is within a preset range.

20. A plasma processing system, comprising:
a chamber providing a space for performing a plasma process on a substrate;
a substrate stage having a seating surface for supporting the substrate, the substrate stage having a circular electrode and at least one annular electrode therein;
a power supply configured to supply source power to an upper electrode provided on the substrate;
a first impedance variator configured to vary an impedance of the circular electrode;
a second impedance variator configured to vary an impedance of the at least one annular electrode;
a sensor connected to the first and second impedance variators respectively and configured to acquire electrical signal data of the circular electrode and the at least one annular electrode; and
a controller configured to determine a thin film profile based on the electrical signal data obtained from the sensor in first and second regions of the substrate respectively corresponding to the circular electrode and the annular electrode, the controller being configured to output first and second control signals respectively in order to obtain a desired thin film profile by using big data having a correlation between the electrical signal data and a deposition rate of the substrate.
